(19) United States
(12) Patent Application Publication
(10) Pub. No.: US 2003/0234644 A1
(43) Pub. Date: Dec. 25, 2003

(54) Force measurement on test and system level test environment under a printed circuit board

(76) Inventors: Rafiqul Hussain, Fremont, CA (US); Richard Block, Daly City, CA (US)

Correspondence Address: FARJAMI & FARJAMI LLP, 16148 SAND CANYON, IRVINE, CA, 92618, US

(21) Appl. No.: 10/180,660

(22) Filed: Jun. 25, 2002

(51) Int. Cl. G01R 1/00

(52) U.S. Cl. 324/158.1

(57) ABSTRACT

A system and method are provided to measure a total force applied by a device to a device under test on a circuit board.

### BACKGROUND OF THE INVENTION

1. Field of the Invention

The present invention relates to testing circuits, and specifically to testing components on a circuit board by applying a proper recommended force.

2. Description of the Related Art

Dies, substrates placed on sockets, which are placed on a circuit board, may be tested once force measured is confirmed and verified to be within a specification.

### SUMMARY OF THE INVENTION

In a test environment, a test is performed with a die/substrate on automated handlers connected to a test system. In a System Level Test (SLT) environment the die/substrate is tested semi-manually on a printed circuit mother board with a thermal head applying pressure on the die and substrate.

A die comprises a silicon material, which is sensitive, and also has solder bumps below the die, which are force sensitive. Force on the substrate is also critical because new packages may have either organic and ceramic substrates and require different amounts of force due to warpage, thickness, and solder connect between die and substrate.

During testing of a die and/or a substrate on a socket in either a test environment or a System Level Test (SLT) environment, it is important to know the proper amount of force to provide the proper conditions for temperature and electrical conductivity. A thermal interface material between the die and a heat sink allows for heat transfer from the die to the heat sink. Such material could be a thermal grease or a carbon-based thermally conductive material. Applying an optimum force and achieving test performance standards in a production setup is desired. With pin lengths and ball diameters for BGA substrates shrinking, along with thinner organic substrates across all types of devices, less force is desired. This desire is amplified when BI-32 or BI-64 systems are used in memory, where 32 or 64 devices are tested simultaneously. In the case of memory chip testing, “BI-32” refers to 32 devices being tested in parallel on a handler. The setup can consist of 1, 8, 16, 32 or 64 devices being tested at a time.

In accordance with the present invention, a system and method are provided to measure a total force applied by a device, such as a thermal head or some other device, to a device under test (DUT), such as a substrate, die and/or socket. In one embodiment, the force is measured under a printed circuit board or an original equipment manufacturer (OEM) motherboard. The system will advantageously help ensure that proper settings for testing are used and maintained across systems. The system may improve reliability, improve precision, improve accuracy, reduce cost of manufacturing, simplify manufacturing and improve wear characteristic. The system may be used to test microprocessors based upon a measured force on the die/substrate.

One aspect of the invention relates to a system configured to measure force applied to a device on a circuit board. The system comprises a first stress relief block configured to support a circuit board; a transducer proximate to the first stress relief block, the transducer being configured to measure an amount of force applied to the device on the circuit board; and a second stress relief block proximate to the transducer. The first and second stress relief blocks are configured to position the transducer.

### BRIEF DESCRIPTION OF THE DRAWINGS

FIG. 1 illustrates one embodiment of a system configured to measure force applied to a DUT or socket.

### DETAILED DESCRIPTION

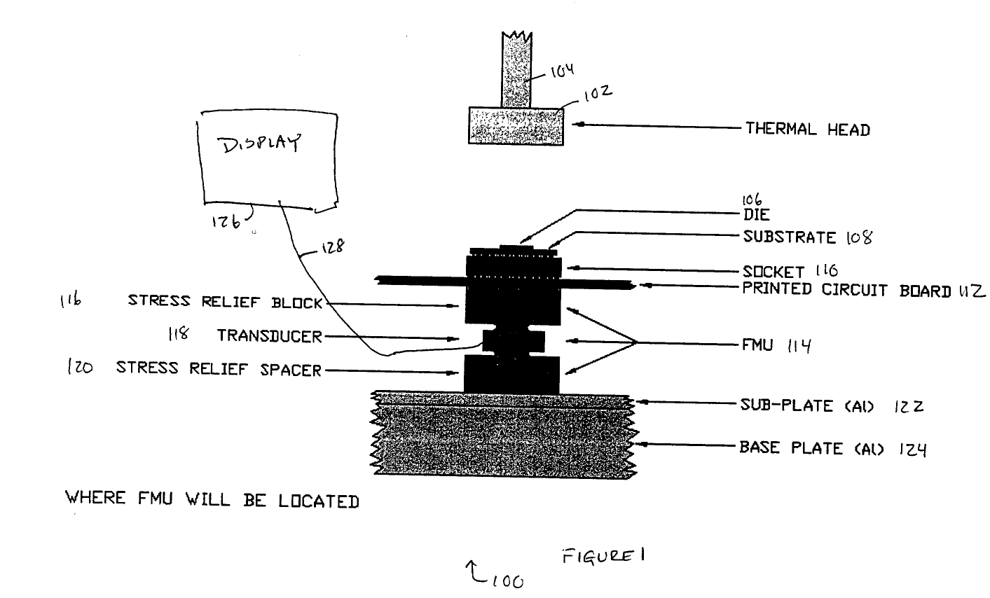

FIG. 1 illustrates one embodiment of a system 100 configured to measure force applied to a DUT or socket 110. The system 100 comprises a shaft 104, a thermal head 102, a die 106, a substrate 108, a socket 110, a printed circuit board 112, a force measurement unit (FMU) 114, a sub-plate 122 and a base plate 124. The system 100 may comprise other components in addition to or instead of the components shown in FIG. 1.

The die may comprise a chip set, a processor or some other integrated circuit. The substrate 108 may be organic or ceramic. The sub-plate 122 and a base plate 124 may be made of aluminum or some other suitable material.

The FMU 114 may replace an aluminum support that would have been placed between the circuit board 112 and the sub-plate 122 in one configuration. In one embodiment, the FMU 114 comprises 3 pieces: a transducer 118, a stress relief block 116 and a stress relief spacer 120. The blocks 116, 120 may be made of Pomalux (plastic) or some other suitable material. The two blocks 116, 120 are used to support the downward force of the thermal head 102 and to position and hold the transducer 118.

The thermal head 102 comprises either an aluminum-based or copper-based heat slug attached to a temperature controller for either cooling or heating the die 106 (or metal lid) or substrate 108 to perform testing at a specified temperature.

In one embodiment, the system 100 may also include a cable 128 and a display 126, such as a digital display, to display the measured force to a user. In one embodiment, the display 126 displays the measured force in real time.

In one embodiment, the transducer 118 has a displacement of about 0.003 inches over its full range of about 200 pounds. In one embodiment, the transducer 118 is linear. The transducer 118 allows for measuring force based on either deflection and/or direct force applied on the die 106 and/or substrate 108. As an example, one specification calls for a load, e.g., heat slug comprising thermo-electric cooler, of about 30 grams per pin. The printed circuit board 112 comes in contact with the socket 110 which has a device, i.e., die 106 and/or substrate 108, plugged in the socket 110. If a device (e.g., substrate 108, socket 110 or printed circuit board 112 comprising electronic components and circuit traces in a multi-layer, which is also known as a mother board) has a total of 462 pins, the total force on the transducer 118 will be about 57.04 pounds or 13,860 grams on the substrate. This means there will be about a (57.04×0.003)/200=0.000856-inch displacement in order for the transducer 118 to take a measurement. Depending on the size of the transducer 118, the transducer 118 could take measurements, but deflection on printed circuit boards is sensitive because the metal traces could break. Thus, minimum force is preferred, but the force should be sufficient to achieve thermal contact. This deflection from the transducer 118, although undesired (minimum deflection allowable without breaking the metal traces on the printed circuit board), should not warp the PC board 112 to the point of losing pin contact.

The above-described embodiments of the present invention are merely meant to be illustrative and not limiting. Various changes and modifications may be made without departing from the invention in its broader aspects. The appended claims encompass such changes and modifications within the spirit and scope of the invention.

What is claimed is:

1. A system configured to measure force applied to a device on a circuit board, the system comprising:
a first stress relief block configured to support a circuit board;
a transducer proximate to the first stress relief block, the transducer being configured to measure an amount of force applied to the device on the circuit board; and
a second stress relief block proximate to the transducer, the first and second stress relief blocks being configured to position the transducer.

2. The system of claim 1, further comprising a sub-plate and a base plate.

3. The system of claim 1, further comprising a display coupled to the transducer, the display being configured to display an amount of force applied to a component on the circuit board.

4. The system of claim 1, wherein the circuit board is a printed circuit board.

5. The system of claim 1, wherein the circuit board is a motherboard.

6. The system of claim 1, wherein the device comprises a die.

7. The system of claim 6, wherein the die comprises a chip set.

8. The system of claim 6, wherein the die comprises a processor.

9. The system of claim 6, wherein the die comprises an integrated circuit.

10. The system of claim 1, wherein the device comprises a substrate.

11. The system of claim 10, wherein the substrate is organic.

12. The system of claim 10, wherein the substrate is ceramic.

13. The system of claim 1, wherein the device comprises a die and a substrate.

14. The system of claim 1, wherein the device comprises a socket.

15. The system of claim 1, wherein the device comprises a substrate and a socket.

16. The system of claim 1, wherein the device comprises a die, a substrate and a socket.

17. The system of claim 1, wherein a thermal head applies the force to the device on the circuit board.

18. The system of claim 1, wherein the stress relief blocks comprise plastic.

19. The system of claim 1, wherein the transducer has a displacement of about 0.003 inches over its full range of about 200 pounds.

20. The system of claim 1, wherein the transducer is linear.

21. The system of claim 1, wherein the transducer is configured to measure a force that is sufficiently small to avoid breaking metal traces on the circuit board and sufficiently large to achieve thermal contact between the device and a thermal head.

22. A system configured to measure force applied to a device on a circuit board, the system comprising:
a first stress relieving means configured to support a circuit board;
a force measuring means proximate to the first stress relieving means, the force measuring means being configured to measure an amount of force applied to the device on the circuit board; and
a second stress relieving means proximate to the transducer, the first and second stress relieving means being configured to position the force measuring means.

23. A method of testing a device on a circuit board, the method comprising:
applying a force on the device; and
measuring a force applied to the device on the circuit board from under the circuit board.
